(19) United States
(12) Patent Application Publication
(10) Pub. No.: US 2025/0336647 A1
(43) Pub. Date: Oct. 30, 2025

(54) FILM DEPOSITION APPARATUS AND FILM DEPOSITION METHOD

(71) Applicant: Tokyo Electron Limited, Tokyo (JP)

(72) Inventors: Satoshi ONODERA, Yamanashi (JP); Jun OGAWA, Yamanashi (JP)

(21) Appl. No.: 19/098,358

(22) Filed: Apr. 2, 2025

(30) Foreign Application Priority Data
Apr. 25, 2024 (JP) 2024-071285

(51) Int. Cl. H01J 37/32; C23C 16/52; H01L 21/02

(52) U.S. Cl. CPC H01J 37/32449; C23C 16/52; H01J 2237/332; H01L 21/0217

(57) ABSTRACT

A film deposition apparatus includes a processing vessel, a first nozzle having a first gas hole for injecting a first processing gas, a second nozzle having a second gas hole for injecting a second processing gas, a shutter to move between positions, a driving source to move the shutter, and a controller to control the driving source. The positions include a first position where the shutter does not cover the first gas hole but covers the second gas hole, and a second position where the shutter covers the first gas hole but does not cover the second gas hole. The controller controls the driving source to move the shutter to the first position when the first processing gas is injected from the first nozzle, and to the second position when the second processing gas is injected from the second nozzle.

### CROSS-REFERENCE TO RELATED APPLICATIONS

The present application is based on and claims priority to Japanese patent application No. 2024-071285 filed on Apr. 25, 2024, with the Japanese Patent Office, the entire contents of which are hereby incorporated by reference.

### TECHNICAL FIELD

The disclosures herein relate to film deposition apparatuses and film deposition methods.

### BACKGROUND

A film deposition apparatus including a gas nozzle for supplying a raw material gas into a processing vessel, and a gas nozzle for supplying a reaction gas into the processing vessel, where the reaction gas reacts with the raw material gas to produce a reaction product, are known (see, e.g., Patent Literatures (PTLs) 1 and 2).

### CITATION LIST

### Patent Literatures

[PTL 1] Japanese Laid-Open Patent Publication No. 2018-148099

[PTL 2] Japanese Laid-Open Patent Publication No. 2020-064949

### SUMMARY

A film deposition apparatus includes a processing vessel that is tubular, extending along a first axis, and configured to house a substrate, a first nozzle extending along the first axis, and having a first gas hole for injecting a first processing gas inside the processing vessel, a second nozzle, extending along the first axis at a different circumferential position in the processing vessel relative to the first nozzle, and having a second gas hole for injecting a second processing gas that reacts with the first processing gas inside the processing vessel to form a reaction product, a shutter configured to move between positions, a driving source configured to move the shutter, and a controller configured to control the driving source, wherein the positions include a first position where the shutter does not cover the first gas hole but covers the second gas hole, and a second position where the shutter covers the first gas hole but does not cover the second gas hole, and the controller is configured to control the driving source to move the shutter to the first position when the first processing gas is injected from the first nozzle, and to the second position when the second processing gas is injected from the second nozzle.

### BRIEF DESCRIPTION OF THE DRAWINGS

FIG. 1 is a vertical sectional view illustrating a film deposition apparatus according to an embodiment;

FIG. 2 is a drawing illustrating an example of a shutter of the film deposition apparatus according to the embodiment;

FIG. 3 is a drawing illustrating a state where the shutter is in a first position;

FIG. 4 is a drawing illustrating a state where the shutter is in a second position;

FIG. 5 is a drawing illustrating a state where the shutter is in a third position;

FIG. 6 is a flowchart illustrating the film deposition method according to the embodiment; and

FIG. 7 drawing is a illustrating a modification of the shutter of the film deposition apparatus according to the embodiment.

### DETAILED DESCRIPTION

In the following, embodiments of the present invention will be described with reference to the accompanying drawings. In the drawings, the same constituent elements are denoted with the same reference numerals, and redundant description related to them may be omitted.

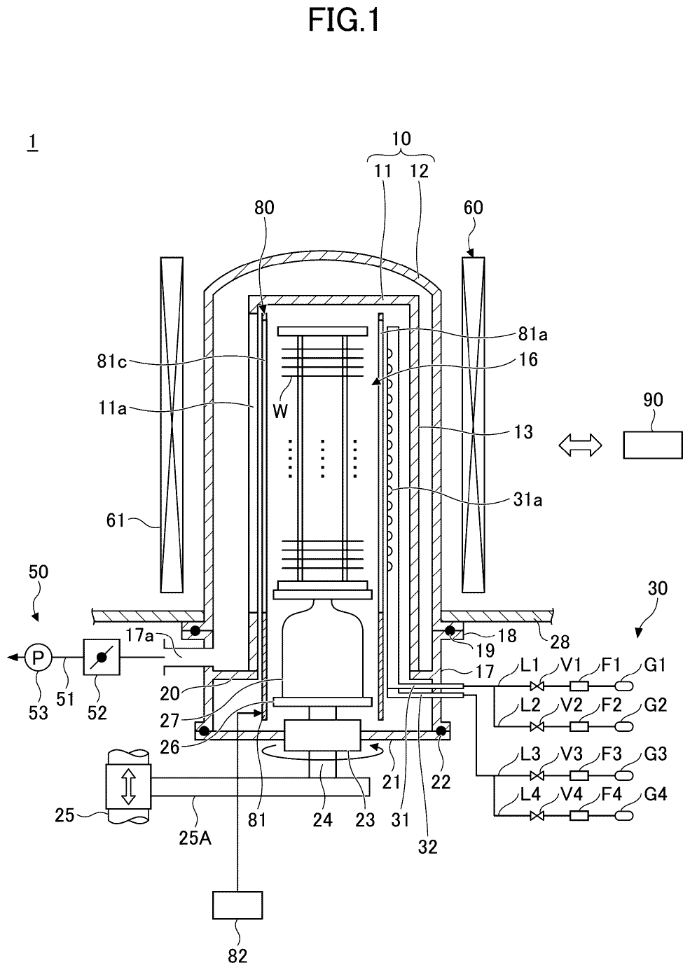

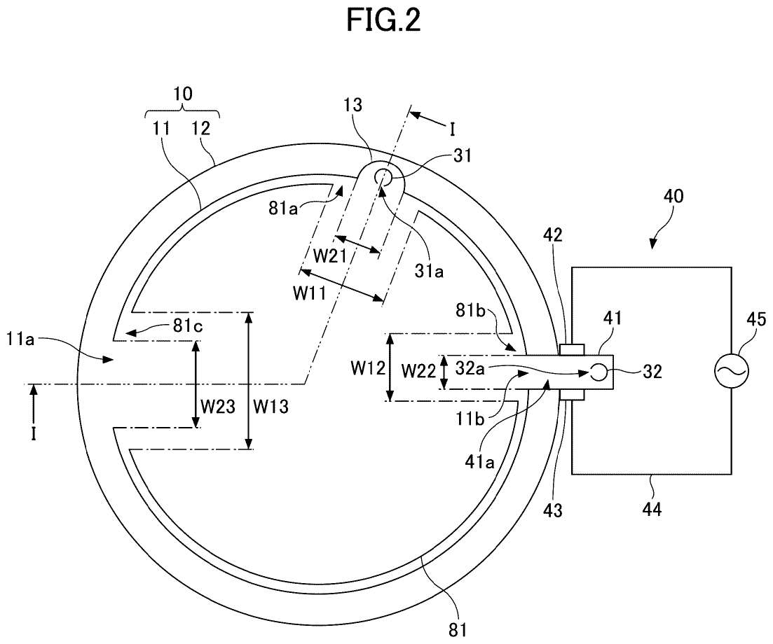

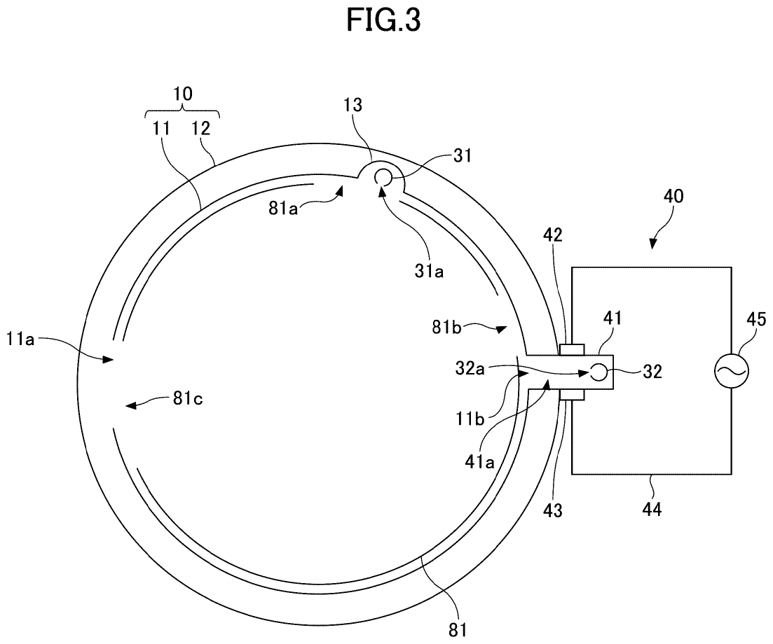

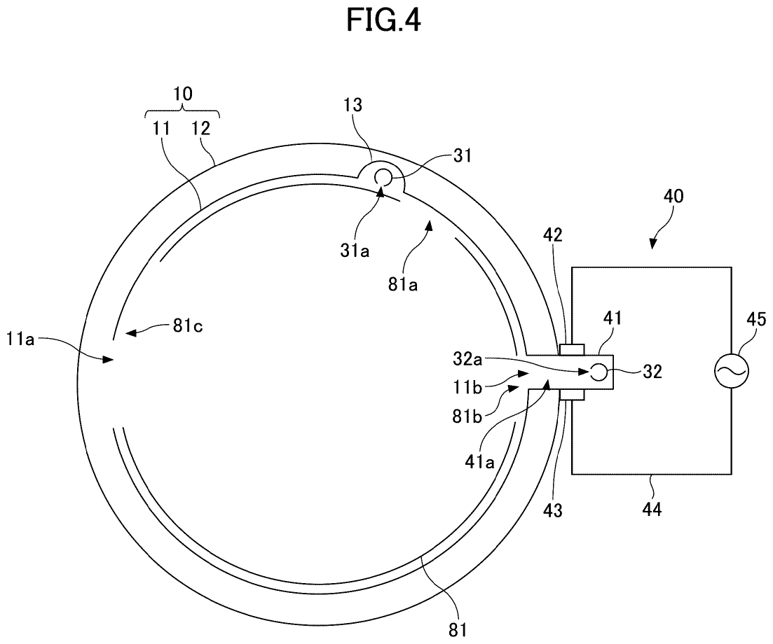

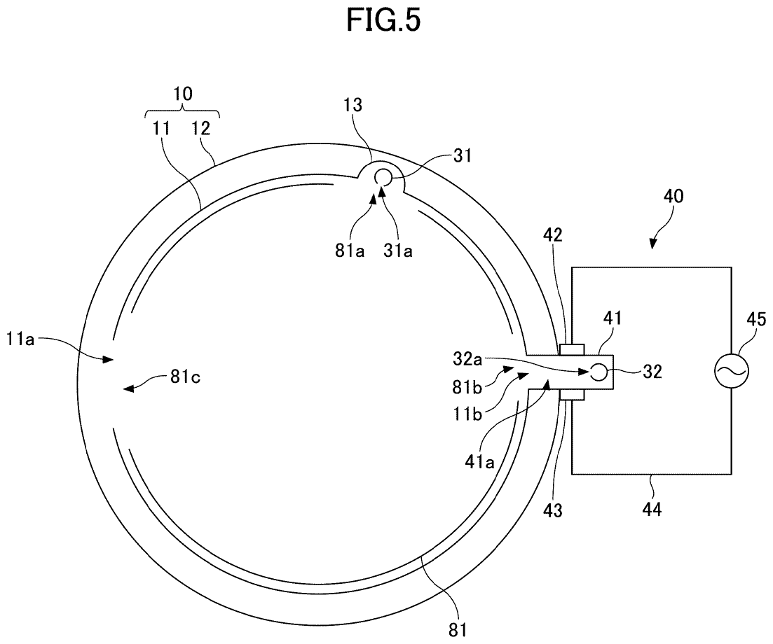

A film deposition apparatus 1 according to an embodiment will be described with reference to FIGS. 1 to 5. FIG. 1 is a vertical sectional view illustrating the deposition film apparatus 1 according to the embodiment. FIG. 2 is a drawing illustrating an example of a shutter 81 of the film deposition apparatus 1 according to the embodiment. FIG. 3 is a drawing illustrating a state where the shutter 81 is in a first position. FIG. 4 is a drawing illustrating a state where the shutter 81 is in a second position. FIG. 5 is a drawing illustrating a state where the shutter 81 is in a third position. FIG. 1 corresponds to a sectional view taken along the line I-I in FIG. 2.

The film deposition apparatus 1 is a batch-type apparatus which performs processing on substrates W simultaneously. The substrates W are, for example, semiconductor wafers. The film deposition apparatus 1 includes a processing vessel 10, a gas supply 30, a plasma generator 40, an exhaust unit 50, a heating unit 60, a movable wall 80, and a controller 90.

The processing vessel 10 can depressurize its interior. The processing vessel 10 has a double tube structure including an inner tube 11 and an outer tube 12. The inner tube 11 and the outer tube 12 are formed of, for example, quartz.

The inner tube 11 has a tubular shape extending along a vertical axis. The vertical axis is an example of a first axis. The lower end of the inner tube 11 is open and the upper end is closed. Openings 11a and 11b are provided on a part of the lateral wall of the inner tube 11. The openings 11a and 11b face each other. The openings 11a and 11b have a rectangular shape extending along the vertical axis. The upper end of the opening 11a and the upper end of the opening 11b are positioned above, for example, the upper end of a boat 16. The lower end of the opening 11a and the lower end of the opening 11b are located, for example, below the lower end of the boat 16. A nozzle housing 13 is provided on a part of the lateral wall of the inner tube 11. The nozzle housing 13 is provided at different positions along the circumferential direction of the inner tube 11 with respect to the openings 11a and 11b. For example, the nozzle housing 13 is provided in the direction of one o'clock, the opening 11b is provided in the direction of three o'clock, and the opening 11a is provided in the direction of nine o'clock. The nozzle housing 13 has a shape in which a part of the lateral wall of the inner tube 11 bulges outward. The nozzle housing 13 houses the first nozzle 31.

The outer tube 12 covers the outside of the inner tube 11. The outer tube 12 has a tubular shape extending along the vertical axis. The lower end of the outer tube 12 is open and the upper end is closed. The lower end of the outer tube 12 is supported by a manifold 17.

The manifold 17 has a tubular shape. The manifold 17 is formed of, for example, stainless steel. A flange 18 is provided at the upper end of the manifold 17. The flange 18 supports the lower end of the outer tube 12. A seal member 19 is provided between the flange 18 and the lower end of the outer tube 12. Thus, the inside of the outer tube 12 is kept hermetic. The seal member 19 is, for example, an O-ring. An annular support 20 is provided on the upper inner wall of the manifold 17. The support 20 supports the lower end of the inner tube 11. An exhaust port 17a is provided on the upper lateral wall of the manifold 17 and above the support 20. A lid 21 is hermetically attached to the opening at the lower end of the manifold 17 via a seal member 22, for example, an O-ring. Thus, the opening at the lower end of the processing vessel 10, that is, the opening of the manifold 17, is hermetically closed. The lid 21 is formed of, for example, stainless steel.

The center of the lid 21 is provided with a rotating shaft 24 penetrating through a magnetic fluid seal 23. The lower part of the rotating shaft 24 is rotatably supported by an arm 25A of a lifting mechanism 25 including a boat elevator.

A rotating plate 26 is provided at the upper end of the rotating shaft 24. The boat 16 is placed on the rotating plate 26 through a quartz heat retaining table 27. The boat 16 rotates by rotating the rotating shaft 24. The boat 16 moves up and down integrally with the lid 21 by raising and lowering the lifting mechanism 25. Thus, the boat 16 is carried into and out of the processing vessel 10. The boat 16 can be accommodated in the processing vessel 10. The boat 16 holds substrates W (e.g., 50 to 150 substrates) substantially horizontally with an interval in the vertical direction.

The gas supply 30 supplies various gases into the processing vessel 10. The gas supply 30 has a first nozzle 31 and a second nozzle 32. The first nozzle 31 and the second nozzle 32 are formed of, for example, quartz. The gas supply 30 may further have another gas nozzle.

The first nozzle 31 has an L-shape, penetrating the lateral wall of the manifold 17 inward, bending upward, and extending vertically along the vertical axis. A vertical portion of the first nozzle 31 is housed in the nozzle housing 13. First gas holes 31a are provided in the vertical portion of the first nozzle 31. The first gas holes 31a are provided at predetermined intervals along the extending direction of the first nozzle 31. Each of the first gas holes 31a is oriented, for example, at the center of the inner tube 11.

A supply line L1 is connected to the first nozzle 31. The supply line L1 is provided with a dichlorosilane (DCS) gas source G1, a mass flow controller F1, and an on-off valve V1 in order from the upstream to the downstream in the gas flow direction. The DCS gas is an example of a first processing gas. The timing of the DCS gas supply from the source G1 is controlled by the on-off valve V1 and adjusted to a predetermined flow rate by the mass flow controller F1. The DCS gas flows into the first nozzle 31 from the supply line L1, and is injected from the first gas holes 31a toward the center of the inner tube 11.

A supply line L2 is connected to the first nozzle 31. The supply line L2 is provided with a nitrogen (N₂) gas source G2, a mass flow controller F2, and an on-off valve V2 in order from the upstream to the downstream in the gas flow direction. The nitrogen gas is an example of a first purge gas. The timing of the nitrogen gas supply from the source G2 is controlled by the on-off valve V2 and adjusted to a predetermined flow rate by the mass flow controller F2. The nitrogen gas flows into the first nozzle 31 from the supply line L2, and is injected from the first gas holes 31a toward the center of the inner tube 11.

The second nozzle 32 is provided at different positions along the circumferential direction of the inner tube 11 with respect to the first nozzle 31. The second nozzle 32 has an L-shape, penetrating the lateral wall of the manifold 17 inward, bending upward, and extending vertically along the vertical axis. The vertical portion of the second nozzle 32 is provided in the plasma generating space 41a. Second gas holes 32a are provided in the vertical portion of the second nozzle 32. The second gas holes 32a are provided at predetermined intervals along the extending direction of the second nozzle 32. Each of the second gas holes 32a is oriented, for example, at the center of the inner tube 11.

A supply line L3 is connected to the second nozzle 32. The supply line L3 is provided with an ammonia (NH₃) gas source G3, a mass flow controller F3, and an on-off valve V3 in order from the upstream to the downstream in the gas flow direction. An ammonia gas is an example of a second processing gas. The timing of the ammonia gas supply from the source G3 is controlled by the on-off valve V3 and adjusted to a predetermined flow rate by the mass flow controller F3. The ammonia gas flows into the second nozzle 32 from the supply line L3, and is injected from the second gas holes 32a toward the center of the inner tube 11.

A supply line L4 is connected to the second nozzle 32. The supply line L4 is provided with a nitrogen gas source G4, a mass flow controller F4, and an on-off valve V4 in order from the upstream to the downstream in the gas flow direction. The nitrogen gas is an example of a second purge gas. The timing of the nitrogen gas supply from the source G4 is controlled by the on-off valve V4 and adjusted to a predetermined flow rate by the mass flow controller F4. The nitrogen gas flows into the second nozzle 32 from the supply line L4, and is injected from the second gas holes 32a toward the center of the inner tube 11.

The plasma generator 40 has a plasma box 41, a pair of plasma electrodes 42 and 43, a power supply line 44, and an RF power supply 45.

The plasma box 41 is provided on a part of the lateral wall of the inner tube 11 to cover the opening 11b. The plasma box 41 hermetically closes the opening 11a. The plasma box 41 extends to the outside of the outer tube 12. The plasma box 41 is formed of, for example, quartz. The plasma box 41 defines a plasma generating space 41a isolated from the space outside the processing vessel 10. The plasma generating space 41a communicates with the inside of the inner tube 11. The plasma generating space 41a is provided with a vertical portion of the second nozzle 32.

The plasma electrode 42 is provided outside one part of the plasma box 41 that extends along the radial direction of the inner tube 11. The plasma electrode 43 is provided outside the other part of the plasma box 41 that extends along the radial direction of the inner tube 11. The plasma electrode 42 and the plasma electrode 43 are arranged to face each other. The plasma electrode 42 and the plasma electrode 43 have a rectangular shape extending along the vertical axis. The power supply line 44 is connected to the plasma electrode 42 and the plasma electrode 43.

The power supply line 44 electrically connects the plasma electrode 42 and the RF power supply 45, and also electrically connects the plasma electrode 43 and the RF power supply 45. The RF power supply 45 supplies RF power to the pair of plasma electrodes 42 and 43. Frequency of the RF power is, for example, 13.56 MHz. When ammonia gas is supplied from the second nozzle 32 and RF power is supplied from the RF power supply 45 to the pair of plasma electrodes 42 and 43, plasma is generated from the ammonia gas in the plasma generating space 41a.

The exhaust unit 50 has an exhaust line 51, a pressure regulating valve 52, and a vacuum pump 53. The exhaust line 51 is connected to an exhaust port 17a. Gas in the processing vessel 10 is exhausted from the exhaust port 17a to the exhaust line 51. The exhaust line 51 is provided with the pressure regulating valve 52 and the vacuum pump 53 in order from the upstream to the downstream in the gas flow direction. The exhaust unit 50 exhausts the gas in the processing vessel 10 by the vacuum pump 53 while adjusting the pressure in the processing vessel 10 by the pressure regulating valve 52.

The heating unit 60 has a heater 61. The heater 61 has a tubular shape and is provided around the outer tube 12. The heater 61 is provided on a base plate 28. The heater 61 heats each substrate W in the inner tube 11. The heating unit 60 may have a heat insulating material.

The movable wall 80 has the shutter 81 and a driving source 82.

The shutter 81 is provided in the inner tube 11. The shutter 81 is provided along a circumference of the inner wall of the inner tube 11. The shutter 81 has a tubular shape. The shutter 81 has a circular shape in plan view orthogonal to the vertical axis. The shutter 81 has a first slit 81a, a second slit 81b, and a third slit 81c. The first slit 81a, the second slit 81b, and the third slit 81c have a rectangular shape extending along the vertical axis. The upper end of the first slit 81a, the upper end of the second slit 81b, and the upper end of the third slit 81c are located, for example, above the upper end of the boat 16. The lower end of the first slit 81a, the lower end of the second slit 81b, and the lower end of the third slit 81c are located, for example, below the lower end of the boat 16. The width W11 of the first slit 81a may be wider than the opening width W21 of the nozzle housing 13. The width W12 of the second slit 81b may be wider than the opening width W22 of the opening 11b. The width W13 of the third slit 81c may be wider than the width W23 of the opening 11a. The first slit 81a, the second slit 81b, and the third slit 81c are provided at different positions along the circumferential direction in the inner tube 11. For example, the first slit 81a is provided in the direction of one o'clock, the second slit 81b is provided in the direction of three o'clock, and the third slit 81c is provided in the direction of nine o'clock.

The driving source 82 moves the shutter 81 between positions by rotating the shutter 81. The driving source 82 includes, for example, a motor. The positions include a first position, a second position, and a third position.

The first position, as shown in FIG. 3, is a position where the shutter 81 does not cover the first gas hole 31a, covers the second gas hole 32a, and does not cover the opening 11a. The first position may be a position where at least a part of the first slit 81a is at a same rotational angle position as the first nozzle 31, and the second slit 81b is at a same rotational angle position as the second nozzle 32.

The second position, as shown in FIG. 4, is a position where the shutter 81 covers the first gas hole 31a, does not cover the second gas hole 32a, and does not cover the opening 11a. The second position may be a position where the first slit 81a is at a rotational angle position different from the first nozzle 31, and at least a part of the second slit 81b is at a rotational angle position same as the second nozzle 32.

The third position, as shown in FIG. 5, is a position where the shutter 81 does not cover the first gas hole 31a, the second gas hole 32a, or the opening 11a. The third position may be a position where at least a part of the first slit 81a is at the same rotational angle position as the first nozzle 31 and at least a part of the second slit 81b is at the same rotational angle position as the second nozzle 32.

The controller 90 is an electronic circuit such as a CPU (Central Processing Unit), an FPGA (Field Programmable Gate Array), or an ASIC (Application Specific Integrated Circuit). The controller 90 executes various control operations described in the present description by executing instruction codes stored in a memory or by designing circuits for special applications.

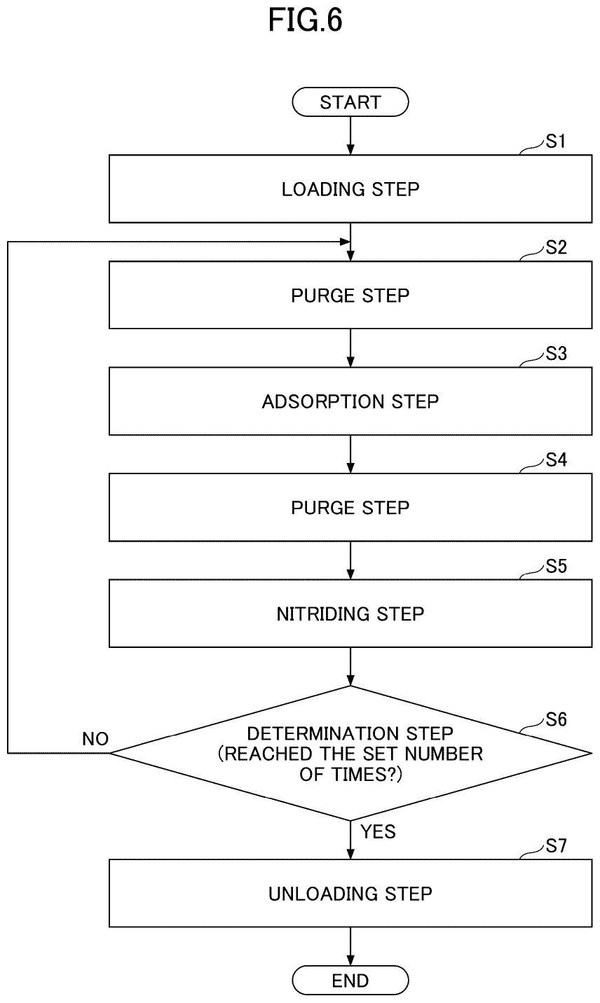

Referring to FIGS. 3 to 6, an operation when the film deposition method according to the embodiment is performed in the film deposition apparatus 1 will be described. FIG. 6 is a flowchart illustrating the film deposition method according to the embodiment. The film deposition method according to the embodiment is performed controlled by the controller 90.

First, the controller 90 executes a loading step S1. In the loading step S1, the lifting mechanism 25 loads the boat 16 holding the substrates W into the processing vessel 10. Subsequently, the lid 21 hermetically closes the opening at the lower end of the processing vessel 10 and seals it. Subsequently, the exhaust unit 50 depressurizes the inside of the processing vessel 10, and the heating unit 60 adjusts the temperature of the substrate W to the film formation temperature.

Next, the controller 90 executes a purge step S2. In the purge step S2, the driving source 82 moves the shutter 81 to the third position (see FIG. 5), and the gas supply 30 injects nitrogen gas from the first nozzle 31 and the second nozzle 32 into the inner tube 11. In the third position, neither the first gas hole 31a nor the second gas hole 32a is covered. In this case, nitrogen gas can be injected from both the first nozzle 31 and the second nozzle 32. Therefore, nitrogen gas can be injected into the inner tube 11 at a large flow rate. As a result, the time required for purging in the processing vessel 10 can be shortened. In the third position, the opening 11a is not covered. In this case, the nitrogen gas injected into the inner tube 11 is exhausted to the exhaust port 17a through the opening 11a.

Next, the controller 90 executes an adsorption step S3. In the adsorption step S3, the driving source 82 moves the shutter 81 to the first position (see FIG. 3), and the gas supply 30 injects the DCS gas from the first nozzle 31 into the inner tube 11. In the first position, the first gas hole 31a is not covered by the shutter 81. In this case, the DCS gas is injected from the first nozzle 31 toward the substrate W. In the first position, the second gas hole 32a is covered by the shutter 81. In this case, diffusion of the DCS gas injected from the first nozzle 31 into the plasma box 41 can be reduced. Therefore, deposition of a silicon nitride film in the plasma box 41 and the second nozzle 32 can be reduced. As a result, generation of particles can be reduced. Conversely, if the silicon nitride film is deposited in the plasma box 41, for example, the silicon nitride film deposited in the plasma box 41 can be peeled off by sputtering by plasma generated from ammonia gas in a nitriding step S5, and particles can be generated. In the first position, the opening 11a is not covered. In this case, the DCS gas injected into the inner tube 11 is exhausted to the exhaust port 17a through the opening 11a. In the adsorption step S3, the gas supply 30 may inject a small flow of nitrogen gas that does not affect the process from the second nozzle 32. In this case, back diffusion of the DCS gas to the supply lines L3 and L4 can be reduced.

Next, the controller 90 executes a purge step S4. The purge step S4 may be the same as the purge step S2.

Next, the controller 90 executes the nitriding step S5. In the nitriding step S5, the driving source 82 moves the shutter 81 to the second position (see FIG. 4), and the gas supply 30 injects ammonia gas from the second nozzle 32 into the inner tube 11. In the nitriding step S5, the RF power supply 45 supplies RF power to the pair of plasma electrodes 42 and 43, which generates plasma from ammonia gas in the plasma generating space 41a. In the second position, the second gas hole 32a is not covered by the shutter 81. In this case, ammonia gas is injected from the second nozzle 32 toward the substrate W. In the second position, the first gas hole 31a is covered by the shutter 81. In this case, diffusion of ammonia gas injected from the second nozzle 32 into the first nozzle 31 can be reduced. Therefore, reaction products generated by the reaction between DCS gas and ammonia gas are not appreciably deposited in the first nozzle 31. As a result, generation of particles can be reduced. In the second position, the opening 11a is not covered. In this case, the ammonia gas injected into the inner tube 11 is exhausted to the exhaust port 17a through the opening 11a. In the nitriding step S5, the gas supply 30 may inject nitrogen gas of a small flow rate which does not affect the process from the first nozzle 31. In this case, back diffusion of the ammonia gas to the supply line L1 and the supply line L2 can be reduced.

Next, the controller 90 executes a determination step S6. In the determination step S6, the controller 90 determines whether the purge step S2, the adsorption step S3, the purge step S4, and the nitriding step S5 have been executed a set number of times. If the number of executions has not reached the set number of times (NO in the determination step S6), the purge step S2, the adsorption step S3, the purge step S4, and the nitriding step S5 are executed again. If the number of executions has reached the set number of times (YES in the determination step S6), the controller 90 advances the process to an unloading step S7. As described above, in the film forming method according to the embodiment, the silicon nitride film is formed on the substrate W by repeating the purge step S2, the adsorption step S3, the purge step S4, and the nitriding step S5 until the number of executions reaches the set number of times.

Next, the controller 90 executes the unloading step S7. In the unloading step S7, the exhaust unit 50 exhausts the gas in the processing vessel 10 to raise the pressure in the processing vessel 10 to the atmospheric pressure, and a cooler (not shown) lowers the temperature in the processing vessel 10 to the unloading temperature. Subsequently, the lifting mechanism 25 unloads the boat 16 from the processing vessel 10.

As described above, according to the embodiment, the controller 90 controls the driving source 82 to move the shutter 81 to the first position when the DCS gas is injected from the first nozzle 31, and to move the shutter 81 to the second position when the ammonia gas is injected from the second nozzle 32. In this case, diffusion of the DCS gas into the plasma box 41 when the DCS gas is injected from the first nozzle 31 can be reduced. Therefore, the reaction product generated by the reaction between the DCS gas and the ammonia gas is hardly deposited in the second nozzle 32 and the plasma box 41. Furthermore, diffusion of the ammonia gas into the first nozzle 31 when the ammonia gas is injected from the second nozzle 32 can be reduced. Therefore, the reaction product generated by the reaction between the DCS gas and the ammonia gas is hardly deposited in the first nozzle 31. As a result, generation of particles can be reduced.

The present invention is not limited to the disclosed embodiment, and various variations and modifications may be made without departing from the scope of the present invention.

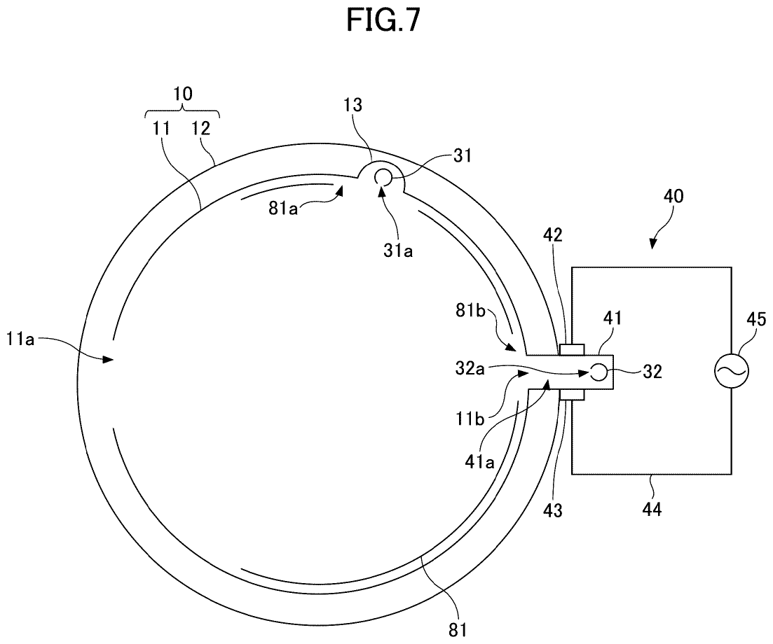

In the above embodiment, the shutter 81 has a circular shape in plan view orthogonal to the vertical axis. However, the present disclosure is not limited to the embodiment described above. FIG. 7 is a drawing illustrating a modification of the shutter 81 of the film deposition apparatus 1 according to the embodiment. As shown in FIG. 7, the shutter 81 may have an arc shape in plan view orthogonal to the vertical axis.

In the above embodiment, the case where the first nozzle 31 is housed in the nozzle housing 13 and the second nozzle 32 is provided in the plasma generating space 41a has been described; however, the present disclosure is not limited to the embodiment described above. For example, the first nozzle 31 and the second nozzle 32 may be housed in the nozzle housing 13. In this case, the film deposition apparatus 1 may not include the plasma generator 40.

In the above embodiment, the case where the first processing gas is DCS gas and the second processing gas is ammonia gas has been described, but the present disclosure is not limited to the embodiment described above. The first processing gas and the second processing gas may be different gases as long as they react with each other to produce reaction products.

According to the present disclosure, generation of particles can be reduced.

What is claimed is:

1. A film deposition apparatus, comprising:
a processing vessel that is tubular, extending along a first axis, and configured to house a substrate;
a first nozzle extending along the first axis, and having a first gas hole for injecting a first processing gas inside the processing vessel;
a second nozzle, extending along the first axis at a different circumferential position in the processing vessel relative to the first nozzle, and having a second gas hole for injecting a second processing gas that reacts with the first processing gas inside the processing vessel to form a reaction product;
a shutter configured to move between positions;
a driving source configured to move the shutter; and
a controller configured to control the driving source,
wherein:
the positions include a first position where the shutter does not cover the first gas hole but covers the second gas hole, and a second position where the shutter covers the first gas hole but does not cover the second gas hole; and
the controller is configured to control the driving source to move the shutter to the first position when the first processing gas is injected from the first nozzle, and to the second position when the second processing gas is injected from the second nozzle.

2. The film deposition apparatus according to claim 1, wherein:
the shutter is provided in the processing vessel along a circumference of an inner wall of the processing vessel; and
the driving source is configured to move the shutter between the first position and the second position by rotating the shutter.

3. The film deposition apparatus according to claim 1, wherein:
the shutter has a first slit and a second slit spaced apart from each other along a circumferential direction in the processing vessel;
the first position is a position where at least a part of the first slit is at a same rotational angle position as the first nozzle; and
the second position is a position where at least a part of the second slit is at a same rotational angle position as the second nozzle.

4. The film deposition apparatus according to claim 1, wherein:
the first nozzle is configured to inject a first purge gas from the first gas hole;
the second nozzle is configured to inject a second purge gas from the second gas hole; and
the controller is configured to cause the second purge gas to be injected from the second nozzle when the first processing gas is injected from the first nozzle, and the first purge gas to be injected from the first nozzle when the second processing gas is injected from the second nozzle.

5. The film deposition apparatus according to claim 1, wherein:
the first nozzle is configured to inject a first purge gas from the first gas hole;
the second nozzle is configured to inject a second purge gas from the second gas hole;
the positions include a third position where neither the first gas hole nor the second gas hole is covered; and
the controller is configured to move the shutter to the third position when injecting the first purge gas from the first nozzle and injecting the second purge gas from the second nozzle.

6. The film deposition apparatus according to claim 1, wherein:
an opening is formed on a lateral wall of the processing vessel;
a plasma box is provided on a part of the lateral wall of the processing vessel to cover the opening of the processing vessel, and configured to define a plasma generating space isolated from a space outside the processing vessel; and
the second gas hole is provided in the plasma generating space inside the plasma box.

7. A method for depositing a film, performed by an apparatus for depositing film including:
a processing vessel that is tubular, extending along a first axis, and configured to house a substrate;
a first nozzle extending along the first axis, and having a first gas hole for injecting a first processing gas inside the processing vessel;
a second nozzle, extending along the first axis at a different circumferential position in the processing vessel relative to the first nozzle, and having a second gas hole for injecting a second processing gas that reacts with the first processing gas inside the processing vessel to form a reaction product;
a shutter configured to move between positions; and
a driving source configured to move the shutter,
wherein the positions include a first position where the shutter does not cover the first gas hole but covers the second gas hole, and a second position where the shutter covers the first gas hole but does not cover the second gas hole,
the method comprising:
injecting the first processing gas from the first nozzle while moving the shutter to the first position; and
injecting the second processing gas from the second nozzle while moving the shutter to the second position.
